(19) United States
(12) Patent Application Publication
(10) Pub. No.: US 2026/0292969 A1
(43) Pub. Date: Sep. 24, 2026

(54) APPARATUS FOR LONG-REACH, LOW-POWER ACTIVE COPPER CHANNELS

(71) Applicant: Ciena Corporation, Hanover, MD (US)

(72) Inventors: Mark Andrew Ferriss, Tarrytown, NY (US); Daniel Rimoli Assumpcao, Garwood, NJ (US); Peter James Pupalaikis, Ramsey, NJ (US)

(21) Appl. No.: 19/575,266

(22) Filed: Mar. 23, 2026

Related U.S. Application Data
(60) Provisional application No. 63/776,708, filed on Mar. 24, 2025.

(51) Int. Cl. H05K 1/02; H03F 3/45; H03H 7/01; H03H 7/03; H04L 25/03

(52) U.S. Cl. CPC H05K 1/023; H03F 3/45085; H03H 7/0138; H03H 7/03; H04L 25/03267; H05K 1/0237; H03F 2200/294; H05K 2201/10734

(57) ABSTRACT

A redriver circuit, apparatus, and method for long-reach, low-power active copper channels. The redriver includes an input block configured to receive signals and a low-frequency attenuator coupled to the input block. The low-frequency attenuator is configured to attenuate low-frequency components of the signals. The redriver includes a low noise front end amplifier coupled to the low-frequency attenuator and configured to provide low-noise amplification to the attenuated low-frequency signals and maintain a target input impedance. The redriver includes an amplifier stage coupled to the low noise front end amplifier and configured to amplify output signals from the low noise front end amplifier. The amplifier stage is configured to provide the amplified output signals.

### CROSS-REFERENCE TO RELATED APPLICATIONS

This application claims priority to U.S. provisional patent application 63/776,708, filed on Mar. 24, 2025. The entire disclosure of the above application is hereby incorporated by reference.

### TECHNICAL FIELD

The technology described in this specification relates to an apparatus for long-reach, low-power active copper channels.

### BACKGROUND

In data centers, such as systems for machine learning (ML) and artificial intelligence (AI) systems involving clusters of compute units, there is a demand for very high-speed connections between compute units. One way for connecting compute units is through passive cables. An example of passive cabling can be dense groupings of twinaxial cable attached to paddle cards on each end, where these paddle cards are designed compatible with the various connectors used for pluggable cables and optics.

### SUMMARY

This disclosed technology provides a redriver circuit and an apparatus for longer reach in active copper cables (ACCs) to provide high-speed, inter-server, communications and connectivity for devices in data centers, such as central processing unit (CPU), graphics processing unit (GPU) in data centers. The devices can be used for machine learning (ML) and artificial intelligence (AI). Other embodiments of this aspect include corresponding computer systems, apparatus, and computer programs recorded on one or more computer storage devices, each configured to perform the actions of the methods.

The present disclosure relates to a redriver circuit to provide active channels between devices, including connectors used for pluggable modules and cables including but not limited to, a Small Form-factor Pluggable (SFP) connector. The redriver circuit reduces noise sensitivity in regions of relatively high noise sensitivity, such as midband frequencies and/or Nyquist frequencies. The disclosed redriver circuit can be tailored for PAM systems, e.g., sequences of 1s and 0s, to provide linearity at lower frequencies (without increasing noise sensitivity) and decrease noise sensitivity at higher frequencies (without decreasing linearity). For example, the redriver circuit can be part of an active copper cable (ACC) arrangement for a channel formed by a cable connecting two optical connectors, each optical connector mounted on a respective printed circuit board that also includes a respective ASIC. The redriver circuit can be designed with fixed parameters that can be for a wide variety of cable lengths and/or signal frequency for signals communicated throughout the channel. The redriver circuit provides for low-power, long-reach, active copper cable with low bit error rate (BER) and increased signal to noise ratio (SNR), without demanding tuning through a communication interface. Furthermore, the active channel can be formed using a minimum number of redriver circuits, e.g., a single redriver circuit, that can be placed on a transmit side or a receive side of the active channel.

The redrivers can be signal conditioning devices that amplify signals, e.g., to reduce any losses that would be weakened by transmission through a chancel, and therefore extend the distance a signal can travel, e.g., extending the length of the channel. As an example, a redriver can be included at the receive side of a channel to amplify a signal transmitted through the cable of the channel, and account for any losses from transmitting signals at the transmit side to the receive side of the channel. A redriver can be optimized using parameters that balance boosting effects (e.g., counteracting losses), noise (e.g., high impact on low signal amplitudes), and distortion/linearity (e.g., high impact on high signal amplitudes).

Implementations may include one or more of the following features.

In a general aspect, a redriver circuit includes: an input block configured to receive signals; a low-frequency attenuator coupled to the input block, the low-frequency attenuator configured to attenuate low-frequency components of the signals; a low noise front end amplifier coupled to the low-frequency attenuator, the low noise front end amplifier configured to provide low-noise amplification to the attenuated low-frequency signals and maintain a target input impedance; and an amplifier stage coupled to the low noise front end amplifier. The amplifier stage can be configured to amplify output signals from the low noise front end amplifier and provide the amplified output signals.

In some implementations, the low-frequency attenuator includes a network configured to allow high frequency signals from the signals to bypass the network.

In some implementations, the amplifier stage includes one or more amplifiers in a cascaded configuration.

In another general aspect, an apparatus includes an active copper channel for connecting a first paddle card to a second paddle card, the second paddle card being different from the first paddle card, and the active copper channel includes a redriver circuit on the second paddle card; and one or more copper cables connecting the first paddle card to the second paddle card. The active copper channel allows for communication of signals between the first paddle card and the second paddle card.

In some implementations, the redriver circuit includes: an input block configured to receive signals; a low-frequency attenuator coupled to the input block, the low-frequency attenuator configured to attenuate low-frequency components of the signals; a low noise front end amplifier coupled to the low-frequency attenuator, the low noise front end amplifier configured to provide low-noise amplification to the attenuated low-frequency signals and maintain a target input impedance; and an amplifier stage coupled to the low noise front end amplifier. The amplifier stage can be configured to amplify output signals from the low noise front end amplifier and provide the amplified output signals.

In some implementations, the apparatus includes an additional redriver circuit on the first paddle card. The additional redriver circuit includes: an additional input block configured to receive signals; an additional low-frequency attenuator coupled to the additional input block, the additional low-frequency attenuator configured to attenuate low-frequency components of the signals; an additional low noise front end amplifier coupled to the additional low-frequency attenuator, the additional low noise front end amplifier configured to provide low-noise amplification to the attenuated low-frequency signals and maintain a target input impedance; and an additional amplifier stage coupled to the additional low noise front end amplifier. The amplifier stage can be configured to amplify output signals from the additional low noise front end amplifier and provide the amplified output signals.

In some implementations, the apparatus includes a first high-speed connector coupled to the first paddle card and connected to a first printed circuit board; and a second high-speed connector coupled to the second paddle card and connected to a second printed circuit board different than the first printed circuit board. In some implementations, at least one of (i) a first application specific integrated circuit (ASIC) is mounted onto the first printed circuit board and (ii) a second ASIC is mounted onto the second printed circuit board. In some implementations, the first ASIC includes (i) a first serializer/deserializer (SERDES) transmit circuit coupled to a first portion of the active copper channel and (ii) a first SERDES receive circuit coupled to the first portion of the active copper channel, and the second ASIC includes (i) a second SERDES transmit circuit coupled to a second portion of the active copper channel different than the first portion of the active copper channel, and (ii) a second SERDES receive circuit coupled to the second portion of the active copper channel.

In some implementations, the first SERDES transmit circuit includes one or more of (i) a first bit sequence generator, (ii) a first SERDES equalizer, (iii) a first SERDES output driver, (iv) a second SERDES output driver, and (v) a first set of package traces. In some implementations, the first SERDES transmit circuit includes the first set of package traces and the first set of package traces include traces between a first SERDES die of the first ASIC and the first printed circuit board. In some implementations, the first set of package traces include traces between the first SERDES die and a ball grid array of the first printed circuit board.

In some implementations, the first SERDES receive circuit includes a second set of package traces between the first printed circuit board and a second SERDES die of the first ASIC. In some implementations, the first SERDES receive circuit includes receive equalizers configured to apply one or more of (i) continuous time linear equalization (CTLE), (ii) feed-forward equalization (FFE), (iii) decision feedback equalization (DFE), or Maximum Likelihood Sequence Estimation (MLSE) equalization.

In some implementations, the second SERDES transmit circuit includes one or more of (i) a second bit sequence generator, (ii) a second SERDES equalizer, (iii) a third SERDES output driver, (iv) a fourth SERDES output driver, and (v) a second set of package traces. In some implementations, the second SERDES transmit circuit includes the second set of package traces and the second set of package traces include traces between a third SERDES die of the second ASIC and the second printed circuit board. In some implementations, the second set of package traces includes traces between the third SERDES die and a ball grid array of the second printed circuit board.

In some implementations, the second SERDES receive circuit includes a fourth set of package traces between the second printed circuit board and a fourth SERDES die of the second ASIC. In some implementations, the second SERDES receive circuit includes second receive equalizers configured to apply one or more of (i) continuous time linear equalization (CTLE), (ii) feed-forward equalization (FFE), (iii) decision feedback equalization (DFE), or Maximum Likelihood Sequence Estimation (MLSE) equalization.

In another general aspect, an apparatus includes an active copper channel for connecting a first paddle card to a second paddle card, the second paddle card being different from the first paddle card, and the active copper channel includes: a redriver circuit on the first paddle card; and one or more copper cables connecting the first paddle card to the second paddle card. The active copper channel can allow for communication of signals between the first paddle card and the second paddle card.

In some implementations, the redriver circuit includes: an input block configured to receive signals; a low-frequency attenuator coupled to the input block, the low-frequency attenuator configured to attenuate low-frequency components of the signals; a low noise front end amplifier coupled to the low-frequency attenuator, the low noise front end amplifier configured to provide low-noise amplification to the attenuated low-frequency signals and maintain a target input impedance; and an amplifier stage coupled to the low noise front end amplifier. The amplifier stage can be configured to amplify output signals from the low noise front end amplifier and provide the amplified output signals.

In some implementations, the apparatus includes an additional redriver circuit on the first paddle card. In some implementations, the additional redriver circuit includes: an additional input block configured to receive signals; an additional low-frequency attenuator coupled to the additional input block, the additional low-frequency attenuator configured to attenuate low-frequency components of the signals; an additional low noise front end amplifier coupled to the additional low-frequency attenuator, the additional low noise front end amplifier configured to provide low-noise amplification to the attenuated low-frequency signals and maintain a target input impedance; and an additional amplifier stage coupled to the additional low noise front end amplifier, wherein the amplifier stage can be configured to amplify output signals from the additional low noise front end amplifier and provide the amplified output signals.

In some implementations, the apparatus includes a first high-speed connector coupled to the first paddle card and connected to a first printed circuit board; and a second high-speed connector coupled to the second paddle card and connected to a second printed circuit board different than the first printed circuit board.

In some implementations, at least one of (i) a first application specific integrated circuit (ASIC) is mounted onto the first printed circuit board and (ii) a second ASIC is mounted onto the second printed circuit board.

In some implementations, the first ASIC includes (i) a first serializer/deserializer (SERDES) transmit circuit coupled to a first portion of the active copper channel and (ii) a first SERDES receive circuit coupled to the first portion of the active copper channel, and the second ASIC includes (i) a second SERDES transmit circuit coupled to a second portion of the active copper channel different than the first portion of the active copper channel, and (ii) a second SERDES receive circuit coupled to the second portion of the active copper channel.

In some implementations, the first SERDES receive circuit includes a second set of package traces between the first printed circuit board and a second SERDES die of the first ASIC.

Particular implementations of the subject matter described in this specification can be implemented to realize one or more of the following advantages. The disclosed redriver also provides a plug-and-play approach for reducing noise sensitivity without demanding additional software programming, link conditioning, and testing. For example, the redriver provides improvement in noise sensitivity independent of loss in the cable and without demanding tuning. The disclosed redriver provides improved flexibility, as the redriver circuit can be placed anywhere in a channel to provide low power and long reach with low bit error rate and increased signal to noise ratio. The disclosed redriver can provide reduced bit error rate by targeting noise sensitive frequencies, rather than maximizing Nyquist-band gain. The disclosed redriver can be seamlessly integrated into a channel without demanding adjustments in devices such as serializers/deserializers in the channel, e.g., no additional receive features are demanded. The disclosed redriver can be used for any cable length and loss, and provides a plug-and-play functionality, e.g., without tuning through an interface. Furthermore, the disclosed redriver can be positioned in a receive-side of a channel with lower power consumption than transmit-side compensation, e.g., by avoiding large transmit swings. The disclosed redriver circuits can be examples of analogic circuits, e.g., circuits that do not have knowledge of the data transmitted and/or any related losses, and thus do not increase computational complexity in serialization, transmission, and deserialization of encoded data in the channel.

Compared to adding a retimed circuit to a printed circuit board of a cable arrangement, a redriver circuit provides reduced power consumption and computational complexity. For example, a retimer can be a circuit configured to decode data from an ASIC at the paddle card and retransmits the data through the cable. A redriver circuit amplifies signals at the paddle card and redrives the data through or from the cables connecting two ASICs, e.g., through two paddle cards. The redriver circuit provides reduced computational complexity and lower power consumption.

Compared to inverting the transfer function of a channel to reduce noise sensitivity of the channel, the disclosed technology provides improved mechanisms for reducing noise sensitivity through multiple portions of a frequency spectrum. For example, the inversion of the transfer function results in an increase in noise sensitivity for some frequencies while also introducing additional programming of registers and adjusting receiver characteristics to account for the inverted transfer function. Thus, the inversion of the transfer function demands tuning of the amount of frequency-dependent gain to add to the system based on host trace loss and/or cable length. The disclosed redriver provides end-to-end noise compensation in the channel without inversion of the low noise sensitivity regions in the frequency spectrum. For example, the disclosed redriver can increase signal gain to reduce noise sensitivity for a target range of frequencies, while also maintaining the reduced noise sensitivity that can occur in another range of frequencies.

The details of one or more implementations of the subject matter described in this specification are set forth in the accompanying drawings and the description below. Other features, aspects, and advantages of the disclosed technology will become apparent from the description, the drawings, and the claims.

Unless otherwise defined, all technical and scientific terms used herein have the same meaning as commonly understood by one of ordinary skill in the art to which this disclosed technology belongs. In case of conflict with patent applications or patent application publications incorporated herein by reference, the present specification, including definitions, will control.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. The dimensions of the various features can be arbitrarily expanded or reduced for clarity.

FIG. 1A is a side view of an example passive copper cable arrangement.

FIG. 1B is an example plot of noise sensitivity vs. frequency.

FIG. 1C is an example plot of channel magnitude response vs. frequency.

FIG. 2A is a side view of an active copper cable arrangement.

FIG. 2B is a top view of an active copper cable arrangement.

FIG. 3A is a block diagram of an example model of a serializer/deserializer transmitter.

FIG. 3B is a block diagram of an example model for an active copper channel

FIG. 3C is a block diagram of an example model of a serializer/deserializer receiver.

FIG. 4 is a diagram of an example redriver circuit.

FIG. 5 is an example plot of a redriver circuit magnitude response.

FIG. 6 is an example plot of signal to noise ratio vs. cable length.

FIG. 7 is an example plot of bit error rate vs. cable length.

FIG. 8 is another example plot of bit error rate vs. cable length.

Like reference symbols in the various drawings indicate like elements.

### DETAILED DESCRIPTION

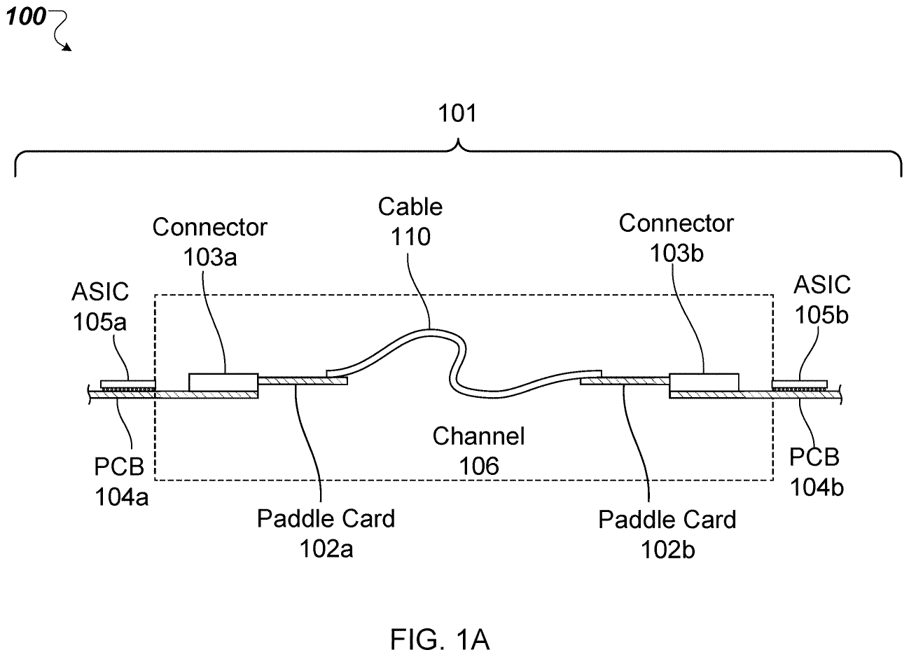

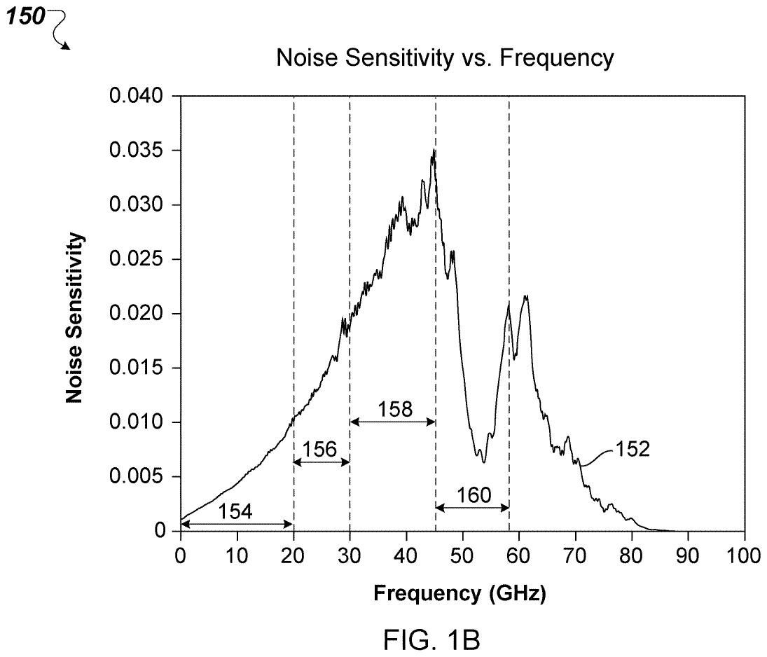

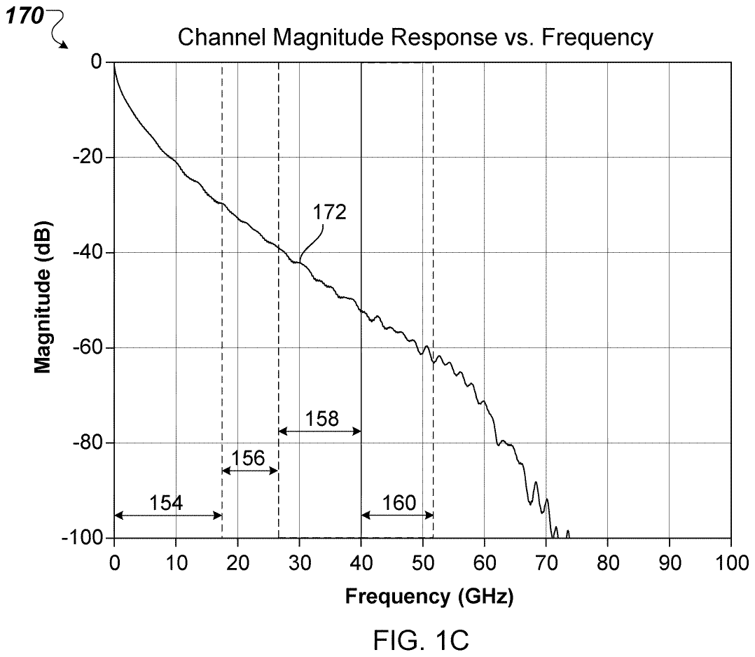

FIG. 1A is a side view 100 of an example passive copper cable arrangement 101. The passive copper cable (PCC) arrangement 101 includes a first application-specific integrated circuit (ASIC) 105a mounted on a first printed circuit board (PCB 104a), and a second ASIC 105b mounted on a second PCB 104b. Examples of ASICs can include high-speed optical-electrical data processing ASICs. The first PCB 104a includes a first connector 103a coupled to a first paddle card 102a. Similarly, the second PCB 104b includes a second connector 103b coupled to a second paddle card 102b. Examples of PCBs 104a and 104b can include switch cards configured to interface with optical pluggable module (“optical pluggable”) and other types of optical transceivers. Examples of the connector 103a and the connector 103b can include Octal Small Form-Factor Pluggables (OSFPs), Quad Small Form-Factor Pluggables (QSFPs), and other types of optical pluggables and transceivers. The paddle cards can provide ground-return paths for high frequency communication between an ASIC and optical pluggable module.

The paddle card 102a and 102b can be connected to each other by a cable 110 to form a communications interface represented by channel 106. Although the view 100 depicts the channel 106 with a single cable, any number of cables can be used to form the communications interface. Examples of the cable 110 can include passive, direct-attach copper cables that provide electrical interconnects between the connectors 103a and 103b through the respective paddle cards 102a and 102b. Referring to the ASICs 105a and 105b (collectively “ASICs 105”) can be any integrated circuit part of a processing unit such as a central processing unit (CPU), graphical processing unit (GPU), or an XPU (e.g., any type and/or combination of processing unit).

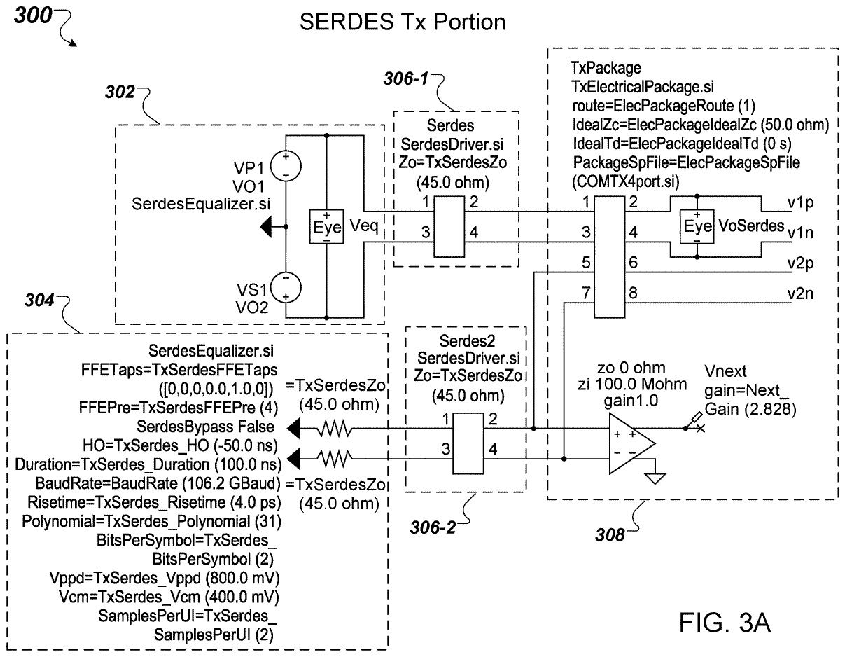

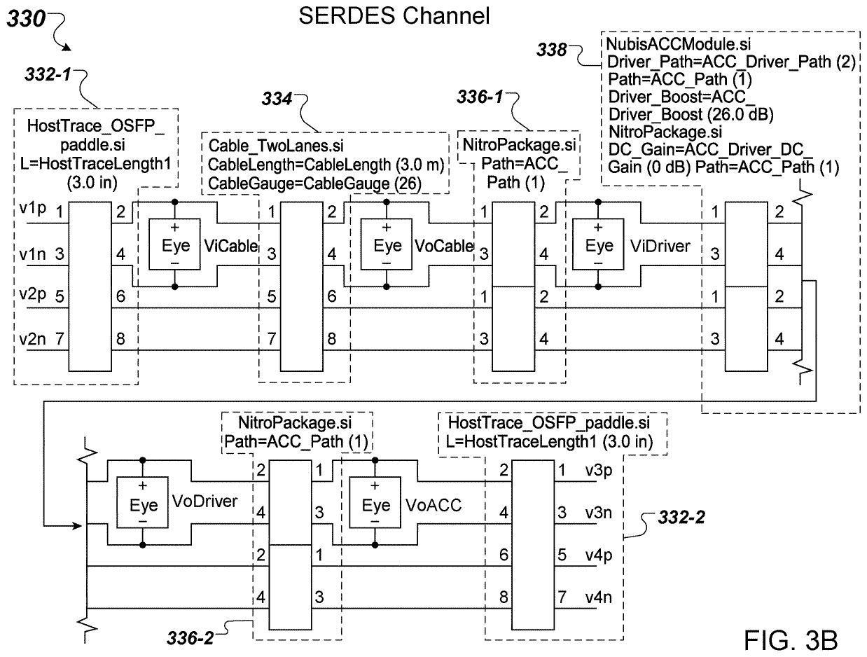

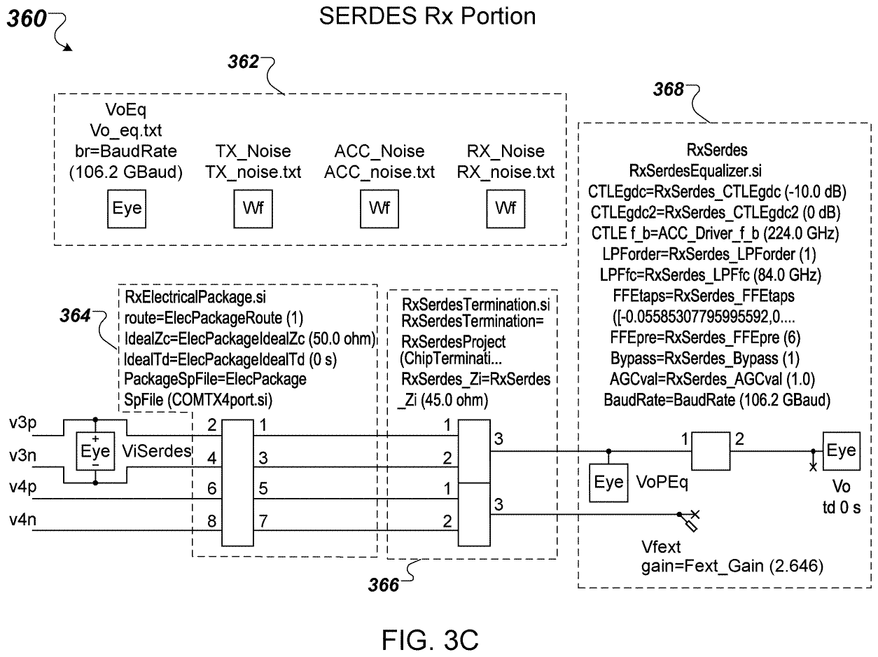

Each of the ASICs 105 can include a serializer/deserializer (SERDES) configured to convert data. For example, and as described in reference to FIGS. 3A through 3C below, an ASIC includes a SERDES Transmit (Tx) portion and a SERDES Receive (Rx) portion. A serializer can be configured to convert data from a relatively wide number of parallel streams (e.g., 256-bit at 1 GHz, 512-bit at 1 GHz) into a fewer number of serial bit streams (e.g., one to four). The serialized data from the ASIC 105a can be transmitted to the ASIC 105b through a number of components in the channel 106. For example, the ASIC 105a transmits the serialized data through the PCB 104a to the connector 103a, to the paddle card 102a, to the paddle card 102b through cable 110, to the connector 103b, and to the ASIC 105b through the PCB 104b. A deserializer in the ASIC 105b can be configured to convert serial bit streams into parallel streams. Further description of SERDES Tx and Rx operations are described further below in reference to FIGS. 3A through 3C below.

The PCC arrangement 101 depicted in view 100 is a passive arrangement for the channel 106, i.e., the PCC arrangement 101 does not include active elements. The PCC arrangement 101 may be preferable for low-power implementations but may not provide sufficient power for the ASICs 105, such as to equalize, decode, and encode data transmitted between the ASIC 105a and 105b using the channel 106.

In some implementations, the PCC arrangement 101 may have a loss in the channel 106 that exceeds a threshold, such that each side of the communications interface formed by the channel 106 is unable to equalize and decode data transmitted over the channel 106. The PCC arrangement 101 may also be unable to accommodate longer reach between a first portion of the arrangement, e.g., ASIC 105a, and a second portion of the arrangement, e.g., ASIC 105b. In some implementations, power demands of a SERDES in an ASIC such as ASIC 105a and/or ASIC 105b may be too high, e.g., exceeding a threshold power demand, in the PCC arrangement 101. Excess power demands can result in extraneous consumption of electric power and related computing resources. Excess power demands can also increase wear and tear on components and generate excess heat that demands additional resources to cool, e.g., to maintain components operating within an operational range of temperatures.

FIG. 1B is an example plot 150 of noise sensitivity vs. frequency, e.g., an example graph. The plot 150 shows simulated data representing noise sensitivity of a channel for an arrangement, e.g., a PCC arrangement described above in reference to FIG. 1A. The plot 150 includes a plotted line 152 indicative of the noise sensitivity over a range of frequencies. The plotted line 152 can be interpreted as the sensitivity of the SERDES receiver or transmitter to input referred noise of the redriver circuit as a function of frequency. At low frequencies, the noise sensitivity of the circuit is lower due to the low signal loss at low frequencies in the cable. At the Nyquist frequency, e.g., mid-band range of 40-50 GHz, there is a decrease in noise sensitivity based on applying nonlinear DFE or MLSE based equalization at the receiver or transmitter. The equalization performed at the SERDES can equalize signals at these frequencies without a corresponding increase in the noise.

The effect of noise for a signal can vary from one portion of the frequency spectrum to another portion of the frequency spectrum. For example, the plotted line 152 indicates a substantially increasing noise sensitivity between 0 GHz and approximately 38 GHz in the plot 150. The plotted line 152 can have a peak noise sensitivity at approximately 41 GHz in the plot 150. The plotted line 152 can indicate a substantial decrease in noise sensitivity at approximately 42 GHz to 52 GHz in the plot 150. The plotted line 152 can indicate an increase in noise sensitivity at approximately 52 GHz to 62 GHz and a decrease in noise sensitivity at approximately 62 GHz to 90 GHz in the plot 150.

At relatively low frequencies, e.g., between 0 and 30 GHz in the plot 150, the circuit can exhibit relatively little noise sensitivity. For example, at close to 0 GHz (DC signals) the circuit can exhibit very little, e.g., close to zero, noise sensitivity. At some portions of the frequency spectrum, such as 50 GHz in the plotted line 152, the noise sensitivity can decrease while the frequency increases. This can be, for example, an overall signal amplitude that is relatively small and relatively insensitive to noise. The portions of the frequency spectrum that correspond with decreased noise sensitivity can correspond to Nyquist frequencies. As the frequency increases, the rate of change for noise sensitivity can also increase. For example, the rate of increase in region 158 of the frequency spectrum in the plot 150 can be greater than the rate of increase in region 156, and a rate of increase in region 156 of the frequency spectrum can be greater than a rate of increase in region 154 of the frequency spectrum in the plot 150.

In the region 160 of the plot 150, there can be a substantial decrease in noise sensitivity at approximately 50 GHz based on applying nonlinear DFE or MLSE equalization at the receiver. Although there is an improvement in noise sensitivity in region 160, the present disclosure relates to a redriver circuit that improves (e.g., reduce) the noise sensitivity at frequencies where the noise sensitivity substantially increases, for example, regions 156 and 158 that are not compensated by the DFE or MLSE equalization at the receiver. One approach for reducing noise sensitivity includes determining the transfer function of the channel and inverting an end-to-end transfer function of the channel in the regions 156 and 158. However, the inversion of the transfer function, e.g., obtaining a broadband gain that mimics a short cable length for the channel, results in an increase in noise sensitivity in multiple regions. Such an approach also demands additional programming of registers and adjusting receiver characteristics to account for the inverted transfer function, thereby demanding tuning of the amount of frequency-dependent gain to add to the system. The tuning for an inversion-based approach is based on host trace loss and/or cable length, and thus changes from one configuration to another.

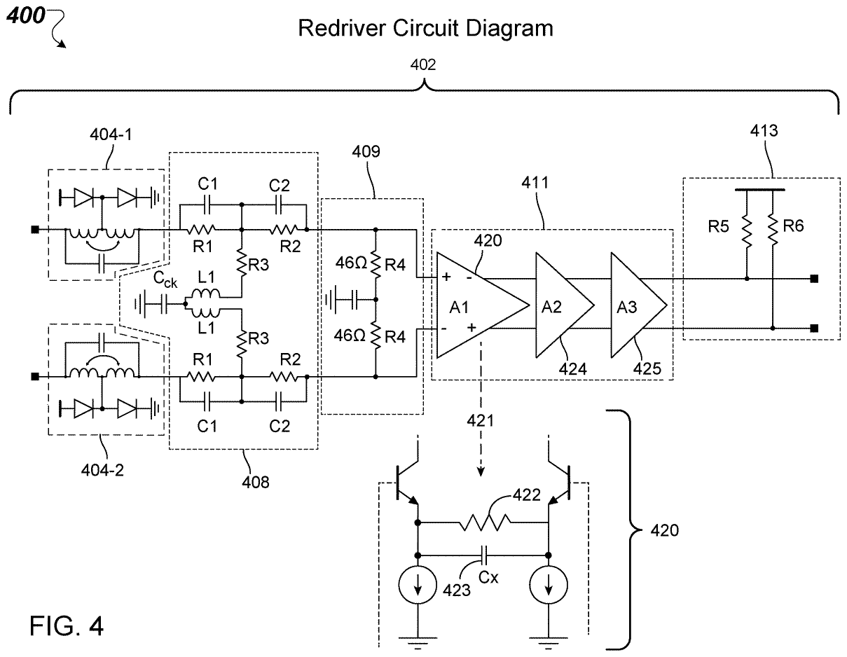

In contrast, the disclosed redriver can be configured to provide end-to-end noise compensation in the channel without inversion of the low noise sensitivity regions in the frequency spectrum. For example, the disclosed redriver can increase, e.g., maximize, signal gain in regions 156 and 158 to reduce noise sensitivity, while also maintaining the decrease in noise sensitivity that occurs in region 160, e.g., compensated by the DFE. The disclosed redriver also provides a plug-and-play approach for reducing noise sensitivity without demanding additional software programming, link conditioning, and testing. For example, the redriver provides improvement in noise sensitivity independent of loss in the cable and without demanding parameter tuning. As described in reference to FIG. 4 below, the disclosed redriver circuit can be optimized with circuit parameters to achieve the target performance, e.g., improved SNR, reduced BER. The disclosed redriver circuit can be used for any host trace loss and cable length.

In some implementations, the reduced noise sensitivity in frequencies at 50 GHz and above can be provided by digital signal processors in an ASIC than other frequencies, e.g., 20-45 GHz. At 50 GHz and higher, SERDES channels in the ASIC can operate in a configuration where signal impairments are predictable high-frequency loses and the DSP of the ASIC can apply equalization techniques, such as those described in reference to FIGS. 3A through 3C below, to compensate for the deterministic, high-frequency distortions. In some cases, some regions such as midband frequencies (e.g., in the 20-45 GHz region) can result in channel impairments that dominate from unpredictable discontinuities at the physical-layer of the channel, e.g., impedance steps at vias, connectors, parasitics, and reflections that produce complex non-linear and frequency-dependent distortions. The discontinuities can result from PCB structures in PCBs connected to the ASICs, parasitic capacitances and inductances, and via/trace transitions, or some combination thereof.

Distortions in the midband frequencies can degrade signal amplitude and edge integrity before the DSP of the ASIC can process the waveform. Furthermore, signals in the midband frequencies (20-45 GHZ) can result in the channel being more vulnerable to common-mode noise, crosstalk, and amplitude imbalance, e.g., particularly for PAM-4 signaling, and thus sensitive to these types of distortions. In some cases, a DSP may have difficulty in correcting these forms of distortion because the distortions occur ahead of the digital frontend and distort the signal in ways that are not appropriately corrected by equalization algorithms.

The present disclosure is redriver circuit that can reduce noise sensitivity in regions of relatively high noise sensitivity, e.g., regions 156 and 158 capturing frequencies in 20 GHz to 45 GHz. The disclosed redriver circuit can be tailored for PAM systems, e.g., sequences of 1s and 0s, to provide linearity at lower frequencies (without increasing noise sensitivity) and decrease noise sensitivity at higher frequencies (without decreasing linearity), such as the above noted midband frequencies.

FIG. 1C is an example plot 170 of channel magnitude response vs. frequency. The plot 170 includes a plotted line 172 representing signal attenuation over a same frequency region depicted in FIG. 1B. The plot 170 shows a total loss of a channel, which can include a package (e.g., ASIC), a host trace, a high-speed connector, a paddle card, and a cable. The plotted line 172 includes the same regions 154, 156, 158, and 160 of FIG. 1B. As an example, the plotted line 172 in the plot 170 depicts relatively little or zero signal attenuation at low frequencies, e.g., approximately 0 GHz. The plotted line 172 in the plot 170 depicts a decrease in the magnitude of the response in the channel, e.g., channel 106 of FIG. 1A, that continues to attenuate as the frequency increases, e.g., towards 70 GHz. In other words, the plotted line 172 can indicate high noise sensitivity in frequencies where loss is relatively high, e.g., region 158. Although the plotted line 172 depicts a loss of approximately 60 dB at Nyquist frequency (e.g., approximately 50 GHz), a low bit error rate can be supported using the redriver circuit, e.g., depicted and described in reference to FIG. 4 below.

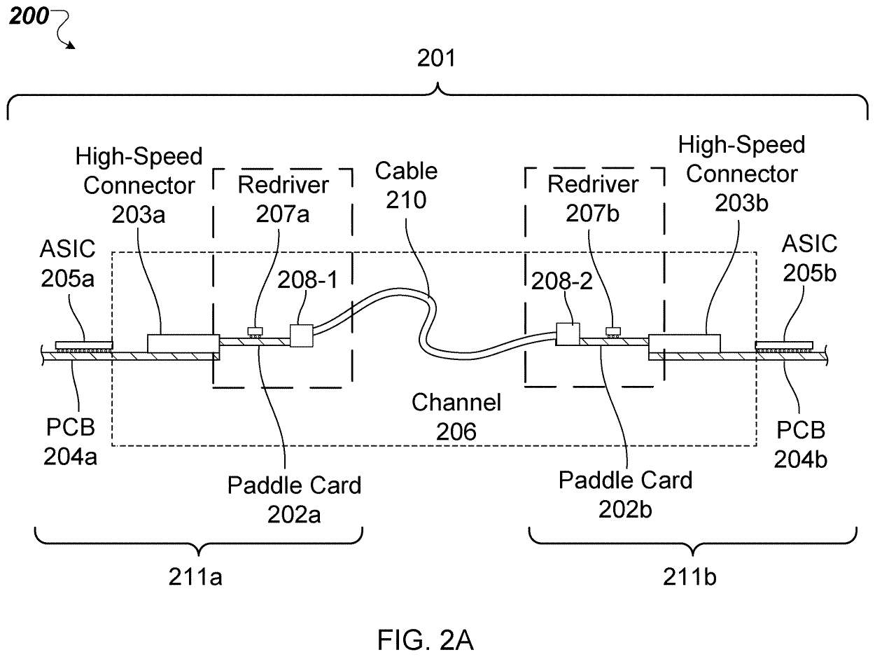

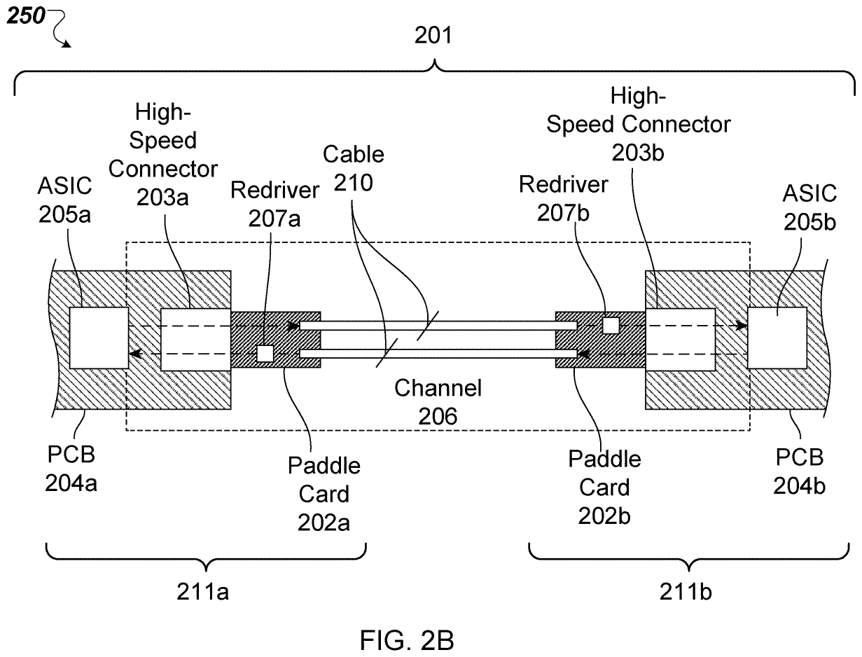

FIG. 2A is a side view 200 of an active copper cable arrangement 201. The active copper cable (ACC) arrangement 201 can be a preferred implementation to send (e.g., transmit, receive) data through channel 206 at a low bit error rate (BER), e.g., a bit error rate below a threshold value. The ACC arrangement 201 is preferred in implementations that account for the loss in a channel, e.g., channel 106, allows for a longer range between the ASICs, e.g., distance between physical displacement of ASIC 205a and 205b of FIG. 2A. The ACC arrangement 201 also reduces a power demand for the SERDES in the ASICs, e.g., compared to the PCC arrangement 101 described in reference to FIG. 1A above.

The ACC arrangement 201 includes ASIC 205a (e.g., an example of ASIC 105a), ASIC 205b (e.g., an example of ASIC 105b), PCB 204a (e.g., an example of PCB 104a), PCB 204b (e.g., an example of PCB 104b), paddle card 202a (e.g., an example of paddle card 102a), paddle card 202b (e.g., an example of paddle card 102b), and a cable 210 (e.g., an example of cable 110). The ACC arrangement 201 also includes a redriver circuit 207a mounted on the paddle card 202a and a redriver circuit 207b mounted on the paddle card 202b. The redriver circuits 207a and 207b may also be referred to as redrivers 207a and 207b, respectively. The addition of a redriver in the channel 206 allows for low-power, long-reach, active copper channel with low bit error rate (BER) and increased signal to noise ratio (SNR), e.g., compared to the PCC arrangement 101 of FIG. 1A.

Although the view 200 of FIG. 2A depicts both redrivers 207a and 207b, the ACC arrangement 201 can include a redriver on a first side 211a of the channel 206 or a redriver on a second side 211b of the channel 206. In other words, the ACC arrangement 201 need not be limited to including redrivers on both sides of the channel 206, e.g., at either or both ends of the cable 210.

The cable 210 is bidirectional and allows for data transmission between different sides of the channel 206, e.g., the channel 206 is bidirectional. In some implementations, the first side 211a can be referred to as the transmit side and the second side 211b can be referred to as the receive side, such as when transmitting signals from the ASIC 205a to the ASIC 205b. Similarly, the first side 211a can be referred to as the receive side and the second side 211b can be referred to as the transmit side, such as when transmitting signals from the ASIC 205b to the ASIC 205a.

In some implementations, the drivers (e.g., the redrivers 207a, 207b, and/or additional redrivers) can be included in connector housings 208-1 and 208-2 for the cable 210. For example, each end of the cable 210 can include a connector housing, e.g., connector housing 208-1 for paddle card 202a and connector housing 208-2 for paddle card 202b, that surrounds connector pins for the cable 210 to connect to the paddle cards 202a and 202b. A redriver can be included in either or both of the connector housings 208-1 and 208-2, e.g., in addition to or instead or redrivers 207a and 207b.

The redrivers 207a and 207b (collectively “redrivers 207”) are examples of analogic circuits, e.g., circuits that do not have knowledge of the data transmitted and/or any related losses. Thus, the redrivers 207a and 207b do not increase computational complexity in serialization, transmission, and deserialization of encoded data in the channel 206. The redrivers 207 can be signal conditioning devices that amplify signals, e.g., to reduce any losses that would be weakened by transmission through a chancel, and therefore extend the distance a signal can travel, e.g., extending a length of the channel 206. As an example, a redriver 207b can be included at the receive side 202b to amplify a signal transmitted through the cable 210 and account for any losses from transmitting signals at the first side 211a to the second side 211b. A redriver can be optimized using parameters that balance boosting effects (e.g., counteracting losses), noise (e.g., high impact on low signal amplitudes), and distortion/linearity (e.g., high impact on high signal amplitudes).

In some implementations, the disclosed redriver can be configured without the use of a Common Management Interface Specification (CMIS) interface. The redrivers 207a and 207b can be examples of broadband amplifiers and the parameters can be tuned to account for noise and linearity. For example, a redriver can be configured as a low noise amplifier (i.e., a noise limited or “noise threshold” amplifier) configured to recover signals that are attenuated to levels substantially close to, e.g., within a threshold value, of a noise floor of the arrangement.

One or both of the redrivers 207a and 207b can be configured to amplify the signal earlier in the signal chain, e.g., prior to transmission over the cable 210, to reduce noise contributions of the active amplifiers degrading the signal-to-noise ratio (SNR) of the transmitted signals. In such implementations, the linearity of the redriver can be de-emphasized as the signal is not yet been amplified above a threshold value to result in non-linear distortion for the redriver. Examples of such low-noise amplifiers (LNAs), e.g., a front end of a radio receiver, as well as transimpedance amplifiers (TIAs), e.g., a front end of an optical receiver.

A redriver can also be configured as a large signal amplifier (i.e., a linearity limited or “linearity threshold” amplifier) configured to amplify signals where an input amplitude of the signal is substantially larger than a noise floor of the amplifier, e.g., exceeds a threshold value, and is further amplified. The magnitude of the signal can be sufficiently large throughout the signal chain in the channel 206, such that the noise contribution is below a threshold value. The redriver can be optimized to balance noise and linearity. For example, and as described in reference to FIG. 4 below, the redriver can be configured using components and values that meet noise thresholds, e.g., a threshold that would otherwise result in relatively poor linearity for large signals at the input due to the relatively high gain of a first stage in the redriver. Similarly, the redriver can be configured using components and values that meet linearity thresholds, e.g., a threshold that would otherwise result in relatively poor noise reduction for signals.

FIG. 2B is a top view 250 of an active copper cable arrangement 201. The view 250 in FIG. 2B depicts placement of the redrivers 207a and 207b, as well as dashed arrows depicting the bidirectionality of the channel 206. For example, a first dashed arrow extends from the ASIC 205a to the channel 206 to indicate a first direction and a second dashed arrow extends from the ASIC 205b to the channel 206 to indicate a second direction. Although FIG. 2B is one example layout for the ACC 201, other example layouts can be represented by the view 250. For example, either of the transmit side and receive sides of the ACC 201 can be found in on top of or below the respective paddle cards in the ACC 201. Similarly, both the transmit and the receive sides can 201 can be found on top of or below the respective paddle cards in the ACC 201.

In some implementations, a redriver circuit can be preferably added to the second side 211b of the ACC arrangement 201. For example, the ACC arrangement 201 can include a redriver 207b without a redriver 207a. This can be desirable to provide compensation in noise and linearity with lower power consumption, e.g., compared to adding redriver circuits to both the first side 211a and second side 211b. Adding the redriver 207b to the second side 211b without adding a redriver 207a to the transmit side can reduce power demand, e.g., without a drastic increase in overall power consumption compared to the power demands for the redriver 207a. For example, adding the redriver 207a can demand a transmitter of the first side 211a to generate relatively large output swings to pre-compensate, e.g., prior to transmitting data over the cable 210, for downstream cable loss, e.g., compared to signal amplitudes without the redriver 207a. A redriver 207b on the second side 211b can processes a small incoming signal and operates on internal high-impedance nodes, allowing high gain at relatively low power, e.g., compared to Tx boosting. Thus, an Rx boosting implementation may be preferred for improved power consumption and efficiency, e.g., compared to both Tx and Rx boosting or Tx boosting alone. Furthermore, the disclosed Rx boosting implementation allows the SERDES to operate without demanding changes to the SERDES, while allowing the redriver 207b to handle signal losses.

In some implementations, the redrivers 207 can be used to form an 8 lane, 200 G Ethernet system to operate at a 1.6 Tb/s transceiver, although any date rate can be supported. In some implementations, the ACC arrangement 201 can be configured to apply forward error correction (FEC), e.g., allocating additional bits to detect and correct errors without re-transmitting the same data. The ACC arrangement 201 can be configured to have any number of lanes and each lane can be configured to transmit and receive pulse amplitude modulation (PAM)-4 data, e.g., at 212.5 Gb/s with a Nyquist frequency of 53.125 GHZ, although any date rate and frequency can be used. For example, the ACC arrangement 201 can be configured to operate between substantially zero, e.g., within a threshold value of zero, frequency (e.g., direct current) and the Nyquist frequency of the ACC arrangement 201, e.g., approximately 53 GHz.

The redrivers 207 can be used to account for the frequency dependent loss in high-speed electrical data communications. For example, a differential mode loss for each cable, e.g., cable 110, can be ⅙ dB/GHz/m, and for a 3 meter cable, can amount to approximately 26.5 dB as shown in Equation 1 below:

$$\frac{1}{6} * \frac{dB}{GHz * m} * 53.1 \; 25 GHz * 3 m \approx 26.5 dB \qquad ( 1 )$$

The redrivers 207 can be designed using a holistic optimization process that balances boost (e.g., to counteract loss) with noise (e.g., impactive at low signal levels) and distortion (e.g., linearity impacted at high signal levels). For example, the redrivers 207 can also account for a nominal loss for each host trace leading to the cable. Example host trace losses can be approximately 16.5 dB for each host trace. In some implementations, the total loss can be over 60 dB (e.g., 16.5 dB per host trace from two host traces and 26.5 dB from the cable) at Nyquist frequency. In addition to equalization techniques performed by the SERDES of the ASICs, the redrivers 207 account for substantial amounts of loss in the channel, including but not limited to 60 dB of loss at Nyquist frequencies as an example. Examples of equalization techniques can include feed-forward equalizer (FFE), continuous-time linear equalizer (CTLE), decision feedback equalizer (DFE), and maximum likelihood sequence estimation (MLSE) detectors. The balancing of losses by the SERDES and redrivers 207 is depicted and described below in reference to FIGS. 3A through 3C. The FIGS. 3A through 3C can be part of a same schematic for the channel 206, e.g., described above in reference to FIGS. 2A and 2B.

FIG. 3A is a block diagram 300 of an example model of a serializer/deserializer transmitter. The SERDES transmitter portion depicted in the block diagram 300 of FIG. 3A can be part of an ASIC, e.g., ASIC 205a, ASIC 205b in FIGS. 2A and 2B. The block diagram 300 depicts a SERDES Feed-Forward Equalization (FFE) module 302, a Pulse Amplitude Modulation N-level (PAM-N) pseudo-random bit sequence (PRBS) generator 304, SERDES output drivers 306-1 and 306-2, and a model 308 of the package traces.

The SERDES FFE module 302 is a serializer/deserializer device that transmits and receives the communications data, as well as adjust shapes of the signal in both the time- and frequency-domains. For example, the SERDES FFE module 302 can employ a sum of weighted delayed portions of the signal, where each weight is a filter coefficient. The delay can be, for example, one or one-half of the unit interval of the symbol being transmitted. The SERDES FFE module 302 is coupled to a first SERDES output driver 306-1, e.g., an output stage of the SERDES that provides power to transmit the signal to a subsequent block in the circuit.

The PAM-N PRBS generator 304 (also referred to as “sequence generator 304”) can provide pulse-amplitude-modulation for a corresponding number of levels per symbol, e.g., 2 levels per symbol, 4 levels per symbol. For example, sequence generator 304 can be a PAM2 sequence generator with 2 levels and configured to transmit one bit per symbol (e.g., high-1 or low-0). The sequence generator 304 depicted in FIG. 3A is an example PAM4 generator with four levels and thus transmits two bits per symbol. The sequence generator 304 can be configured based on bandwidth and SNR performance, e.g., leveraging higher levels of PAM to transmit more bits in lower bandwidth but demanding improved SNR to distinguish the levels from each other.

The sequence generator 304 can be configured to generate multi-level bit pattern, such as by producing a two-bit symbol stream, each symbol corresponding to one of four discrete amplitude levels used in PAM4 signals. The sequence generator 304 can leverage different types of digital sequence-generation techniques, e.g., linear feedback shift registers, to generate a pseudo-random sequence of bit pairs representing an input data stream. The output of the sequence generator 304 can be provided to a second SERDES output driver 306-2. Similar to the first SERDES output driver 306-1, the second SERDES output driver 306-2 provides the output of the sequence generator 304 to a subsequent module in the circuit, e.g., the model 308 of package traces.

The model 308 of package traces depicted in the block diagram 300 can represent package traces between a SERDES die and ball grid array (BGA) bumps on a host PCB, e.g., PCB 204a, for an ASIC, e.g., ASIC 205a. The SERDES Tx portion depicted in FIG. 3A can be part of the ASIC, e.g., ASIC 205a, 205b. In some implementations, ICs can be mounted on packages configured to resolve differences in pitch between the IC connection (e.g., very fine pitch) and the printed circuit board (PCB) connection (e.g., a lower pitch than the IC connection). The model 308 of package traces can represent signal traces built inside the packages.

FIG. 3B is a block diagram 330 of an example model for an active copper channel. The block diagram 330 represents the change of an ACC arrangement, e.g., ACC arrangement 201. The block diagram 330 depicts a block 332-1 and a block 332-2 on each side of the channel. Each of the blocks 332-1 and 332-2 representing a combination of (i) a host trace on the printed circuit board of an ASIC in the channel, (ii) a high-speed connector (e.g., an optical connector such as an OSFP), and (iii) a paddle card. For example, the block 332-1 can represent the PCB 204a, the high speed connector 203a, and the paddle card 202a, described above in reference to FIGS. 2A and 2B. Similarly, the block 332-2 can represent the PCB 204b, the high speed connector 203b, and the paddle card 202b, also described above in reference to FIGS. 2A and 2B.

The block diagram 330 also includes a block 334 representing a model of the cables in the channel, e.g., cables 210 of the channel 206. The block diagram 330 includes a block 338 representing a driver IC model for a redriver, such as redriver 207b or 207a described above in reference to FIGS. 2A and 2B. The block diagram 360 depicts block 338 having a block 336-1 and 336-2 on both sides of the block 338. The blocks 336-1 and 336-2 can include package housings for the redriver IC, e.g., block 336-1 representing a package housing for a first side of the redriver IC and block 336-2 representing a package housing for a side opposite the first side of the redriver IC. As described above in reference to FIGS. 2A and 2B, the ACC arrangement 201 can include a redriver IC in the receive side of the arrangement 201 without a redriver IC in the transmit side, such as to reduce noise sensitivity with less power consumption, e.g., compared to redrivers on both the transmit side and the receive side.

FIG. 3C is a block diagram 360 of an example model of a serializer/deserializer receiver. The SERDES receiver portion depicted in the block diagram 360 of FIG. 3C can be part of an ASIC, e.g., ASIC 205a, ASIC 205b in FIGS. 2A and 2B. The block diagram 360 includes a block 364 representing a model of package traces between ball grid array bumps on a second PCB, e.g., different than a first PCB for the SERDES transmitter, as well as ball grid bumps and the SERDES die. The block 364 can provide signals to the block 366. The block 366 represents a termination structure in the SERDES die in the ASIC and can provide signals to the block 368 representing the SERDES receiver. The termination structure represented by the block 366 can indicate termination of the channel by the receiver, such as by using a resistor network that is matched to the characteristic impedance of the channel. The termination structure represented by the block 366 can be inside an ASIC die that includes the respective SERDES receiver.

The block 368 representing the SERDES receiver can include receiver equalizers. Examples of equalizers can include Continuous-Time Linear Equalizer (CTLE), Feed Forward Equalizers, Decision-Feedback Equalizers, and Maximum-Likelihood Sequence Estimation detectors, or some combination thereof. The block 368 can be used to generate an eye diagram, e.g., a simulation of channel performance, that can be used to determine quality of data transmission through the channel. The block 368 can also have a far-end-crosstalk (FEXT) pick-off that is used to determine crosstalk noise to be considered when determining the transmission quality.

The block 362 represents example waveforms for a simulation of the circuit. The example waveforms can be calculated offline and can include the equalized signal, the transmitter noise, the input referred noise to the ACC arrangement, and the noise at the receiver. Although the block 362 represents a model of the waveforms, the waveforms can be measured or obtained from the physical circuit.

FIG. 4 is a diagram of an example redriver circuit 402. The diagram 400 shows the redriver circuit 402 that includes input blocks 404-1 and 404-2 (collectively “input block(s) 404), a low-frequency attenuator 408 coupled to the input blocks 404, a low noise front end amplifier 409 coupled to the low-frequency attenuator 408, and an amplifier stage 411 coupled to the low noise front end amplifier 409. The circuit 402 can include an output termination block 413 coupled to the amplifier stage 411. The components (e.g., blocks 404, 408, 409, 411, 413) can be configured using circuit parameters that reduce noise sensitivity mid-band frequencies (e.g., approximately 20 to 50% of the Nyquist frequency such as approximately 10 GHz to 40 GHz) while also maintaining linearity at lower frequencies, e.g., 0-10 GHz. Thus, the redriver circuit 402 has an architecture that reduces noise for mid-band frequency ranges and maintains linearity at lower frequencies.

The input blocks 404 of the redriver circuit 402 are configured to receive signals. For example, the redriver circuit can be redriver circuit 207a and the signals can be received from a transmit-side high-speed connector, e.g., high-speed connector 203a, or from a receive-side high-speed connector, e.g., high-speed connector 203b, through a cable 210. As another example, the redriver circuit can be redriver circuit 207b and the signals can be received from a receive-side high-speed connector, e.g., high-speed connector 203b, or from a transmit-side high-speed connector, e.g., high-speed connector 302a, through a cable 210.

Each of the input blocks 404 can be a center-tapped inductive peaking network coupled to a shunt capacitor, e.g., to increase enhance broadband frequency response. The center-tapped inductive peaking network in each input block can be coupled to a pair of diodes that provide symmetrical voltage limiting and transient protection at the amplifier input of the redriver circuit. The circuits in each of the input blocks 404 can be coupled inductor-capacitor networks that provide bandwidth-extension, e.g., compensating for high-frequency roll-off in the photodiode or transimpedance stage from optical high-speed connectors. The diode pairs in each of the input blocks 404 can be configured to clamp large and/or rapid voltage excursions generated by optical-to-electrical conversion, such as to reduce overload in downstream electronics.

The low-frequency attenuator 408 is coupled to the input blocks 404 and configured to attenuate low-frequency components of the signals. The low-frequency attenuator 408 can include a resistor network that includes R1, R2, and R3 to attenuate signals at low-frequencies (e.g., low-frequency portions of a signal and/or signals with low-frequencies), while maintaining impedance matching for amplification in later stages of the redriver circuit 402. The low-frequency attenuator 408 reduces the likelihood of hard compression from large low frequency content of signals, e.g., by attenuating the signals at low-frequencies prior to amplification. The high-frequency signals can bypass the low-frequency attenuator 408 using the C1, C2, and L1 network, such as to allow high frequency portions of a signal and/or high-frequency signals to pass through the low-frequency attenuator 408 with little to zero attenuation. The low-frequency attenuator 408 includes a capacitor Cck connected between two portions of the low-frequency attenuator 408, e.g., subnetworks that each include C1, C2, R1, R2, R3, and L1. The capacitor Cck can be configured to provide high-frequency coupling between the differential outputs of each subnetwork, to create a compensating zero that cancels an internal pole of the subnetworks and stabilizes the subnetworks by reducing distortion.

The low noise front end amplifier 409 is coupled with the low-frequency attenuator 408. The low noise front end amplifier 409 is configured to provide low-noise amplification to the attenuated low-frequency signals and maintain a target input impedance. For example, the low noise front end amplifier 409 provides a relatively high gain, e.g., 10 dB at Nyquist frequency, to reduce noise while also amplifying the low-frequency portions of a signal and/or low-frequency signals. Prior to the amplification by the amplifier stage 411, the low noise front end amplifier 409 can provide rapid, substantial amplification.

The low-noise front-end amplifier can be configured to receive and amplify input signals while introducing a minimal amount of additional noise, thereby preserving a signal-to-noise ratio of the input signal. The amplifier can be at an input block of a signal processing chain, e.g., of a circuit, and can be configured to low noise amplification through device sizing, biasing, and impedance matching at the input node of the circuit. The low-noise front-end amplifier may be preferable to preserve signal integrity at relatively low signal levels.

In some implementations, the low noise front end amplifier can be a shunt-feedback amplifier. The shunt-feedback amplifier can be a feedback network coupled between an output node and an input node to provide negative feedback in a shunt configuration. The feedback network stabilizes amplifier gain, extends bandwidth, and can define input and output impedances. The shunt-feedback amplifier may be desirable to provide broadband operation, impedance control, or gain stability.

The amplifier stage 411 is coupled to the low noise front end amplifier 409 and can be configured to amplify output signals from the low noise front end amplifier 409. The amplifier stage 411 can be configured to provide amplified signals for output, e.g., to an output termination block 413. The amplifier stage 411 can include cascaded amplifiers A1, A2, and A3, depicted in the diagram 400 as a first amplifier 420, a second amplifier 424, and a third amplifier 425. A close-up view 421 of the diagram 400 shows the first amplifier 420 in more detail and each of the second and third amplifiers 424 and 425 can include a similar network as the network shown in close-up view 421.

The circuit 402 includes the low noise front end amplifier 409 and the amplifier stage 411 to maintain linearity and preserve sensitivity in the target frequency band, by introducing frequency-selective attenuation at low frequencies and bypasses the same attenuation at higher frequencies, e.g., using passive components C1, C2, and L1. The capacitors C1 and C2 of the low noise front end amplifier 409 shunt low-impedance paths at high frequency, while the inductor L1 removes the resistive degeneration component.

The view 421 shows a differential input pair of the first amplifier 420 implemented using bipolar transistors and a shunt capacitor 423 (depicted in FIG. 4 as Cx) that is used to introduce a compensating zero that counteracts internal poles and restores high-frequency gain. By sizing the shunt capacitor 423 sufficiently large, the shunt capacitor 423 lowers impedance early enough to bypass the degeneration network while also avoiding introduction of the compensating pole until above the frequency band of interest. The result is a controlled transition from low-frequency attenuation to high-frequency gain, preventing saturation at low frequencies while maintaining wideband, high-speed amplification near the Nyquist limit.

The view 421 shows the first amplifier 420, which can be part of a chain of broadband amplifiers that includes the second amplifier 424 and the third amplifier 425. The view 421 shows the first amplifier 420 having an emitter degenerated differential pair, where the degeneration includes a parallel combination of a differential pair resistor 422 and a differential pair capacitor 423 (depicted in the view 421 as Cx) to introduce a compensating zero that counteracts internal poles and restores high-frequency gain. The capacitor 423 can be referred to as a shunt capacitor 423. The first amplifier 420 can be configured to provide low gain at relatively low frequencies and high gain at relatively high frequencies, where the transition from low gain to high gain provides the desired equalization, e.g., at mid-band frequencies near or approximate to the Nyquist frequency.

The first amplifier 420 can be a Continuous-Time Linear Equalizer (CTLE) configured to compensate for frequency-dependent channel loss, e.g., by attenuating low-frequency components and boosting high-frequency components in real time. The first amplifier 420 can be used along with a cross-coupled capacitors (Cck) in the low-frequency attenuator 408 to introduce controlled zeros configure to counteract a dominant pole. The first amplifier 420 can provide broadband linear equalization that prepares the signal for subsequent amplifiers, e.g., amplifiers 424 and 425.

The amplifiers, e.g., amplifiers 420, 424, 425, in the amplifier stage 411 can be fixed CTLEs (e.g., using a same set of parameters, values, etc.) that do not demand programming, while also being suited for a range of cable lengths and losses. For example, the amplifier stage 411 of the redriver circuit 402 can provide corrections for channel losses that exceed an available peak of one amplifier, e.g., maximum peaking of a CTLE such as a first amplifier 420.

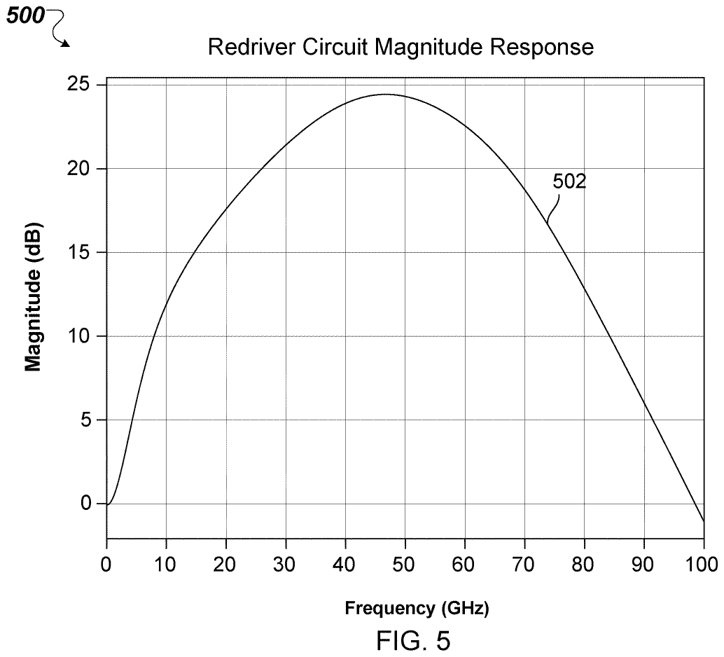

The amplifier stage 411 provides the output signals to the output block 413 and the output block 413 can include resistors R5 and R6. The resistors R5 and R6 can have the same values, e.g., 46 Ohms. An example magnitude response of the circuit 402 is depicted in FIG. 5. The output block 413 includes resistors R5 and R6 to set the output impedance of the redriver circuit 402. As an example, R5 and R6 can each have resistor values of 46 Ohms for the output termination of the redriver 402, e.g., nominal values of 92 Ohms. Similarly, both resistors R4 in the low noise front end amplifier 409 can also have matching resistor values to set the differential input, e.g., nominal values of 92 Ohms.

FIG. 5 is an example plot 500 of a redriver circuit magnitude response. The plot 500 shows a peak response of the redriver circuit, e.g., redriver circuit 402 described above in reference to FIG. 4, that occurs at approximately 45 GHz. This allows for improved response in a mid-band portion, to provide a high gain regime in and approximately near the Nyquist frequency. Although the plot 500 in FIG. 5 is one example redriver circuit magnitude response, other variations of the magnitude response curve are possible with different parameters for the redriver circuit. The plotted line 502 shows a signal gain greater than 20 dB with a peak response around 45 GHZ, e.g., to reduce noise sensitivity at 45 GHz and thereby provide a high SNR that is supported for the full channel, e.g., channel 206. The plot 500 can provide an improved SNR for the different noise sources, which provide metrics used to evaluate the relative impact of the different noise sources, in addition to the overall bit error rate of the channel for different configurations.

For example, the parameters and the design of the redriver 402 can be selected based on noise and linearity. Sources of noise can include transmitter noise (e.g., set to −33 dBc). The transmitter noise can white noise integrated to the Nyquist frequency, e.g., relative to the main cursor in the transmitter based on a channel operating margin specification. Another source of noise can include receiver noise set to a white noise density η₀=4.2 nV²/Hz based on a COM specification for the receiver.

Another source of noise can include active copper channel (ACC) noise that can be set as a colored noise density. The noise density can be simulated using different parameters for the redriver 402 and can include contributions such as near-end crosstalk (NEXT) noise and far-end crosstalk (FEXT) noise. The NEXT noise can be determined, e.g., by simulation, based on the Vₙₑₓₜ pick-off in the TX schematic portion shown in FIG. 3A. The NEXT noise can be multiplied by \sqrt{8} (or ~2.828) to represent the statistics associated with 8 neighboring signal channels, e.g., located at the same end of the link as the victim channel and whose switching activity induces near-end crosstalk (NEXT) into the victim channel. Similarly, the FEXT noise can be determined, e.g., based on simulation, of V_{fext} pick-off in the RX schematic portion shown in FIG. 3C. The FEXT noise can be multiplied by \sqrt{7} (or ~2.646) to represent the statistics of 7 far-end neighboring signal channels.

In some implementations, the above-mentioned noise sources can be modeled with transfer characteristics that include noise injection site to the receiver, which can be multiplied by the noise density at the noise injection site, and integrated to form a noise contribution for a given noise source. The noise contributions can be added in quadrature to produce a total noise contribution at the receiver, which can be utilize with random jitter of 90 fsᵣₘₛ and a dual-Dirac deterministic jitter of 180 fsₚₖₚₖ, to form a kernel that is smoothed over a resulting eye diagram generated at the receiver in order to determine the final bit error rate.

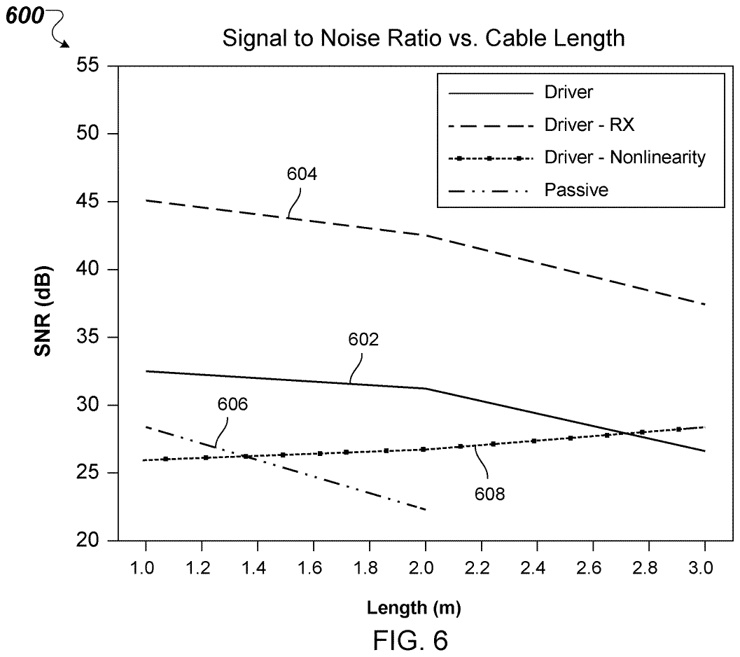

FIG. 6 is an example plot 600 of signal to noise ratio (SNR) vs. cable length. The plot 600 includes plotted lines 602, 604, 606, and 608. The plotted line 606 depicts the SNR of a passive channel without a redriver, and thus the passive channel SNR is limited by noise and degrades as the cable length increases, e.g., 22 dB at approximately 2 meters of cable length. The plotted line 604 is an example with the redriver inserted in the channel and provides increases SNR at the receiver, such that the redriver RX SNR indicated by plotted line 604 increases by greater than 15 dB, e.g., enabling communication for cables greater than 2 meters and overall improved communication at shorter lengths. The plotted lines 602 and 608 are associated with driver noise and driver nonlinearity associated with the driver. For example, the plotted line 602 can model the driver noise that can degrade over time as the cable length increases, e.g., the signal reaching the driver becoming more attenuated. As another example, the plotted line 608 is the driver non-linearity that can be introduced for relatively short cable length, e.g., 1 meter, where a swing of the input of the driver is large. The plotted lines 602 and 608 can be optimized, e.g., accounted for using the redriver circuit 402, such as to provide the improved performance indicated by plotted line 604. For example, the redriver circuit can provide high SNR in plotted lines 602 and 608 for all cable lengths.

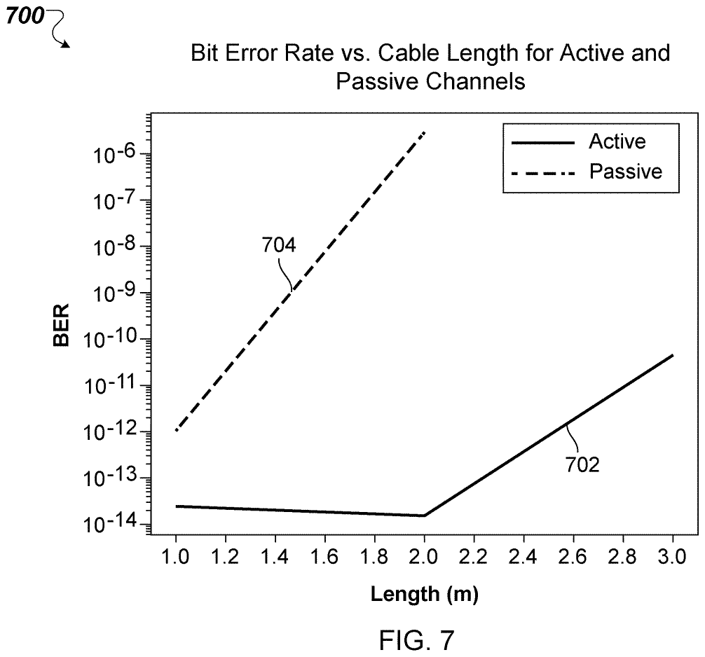

FIG. 7 is an example plot 700 of bit error rate vs. cable length. The plot 700 shows a plotted line 704 indicative of bit error rate for a passive copper channel (PCC) arrangement or a “passive” channel. The plot 700 shows a plotted line 702 indicative of bit error rate for an active copper channel (ACC) arrangement or a “active” channel. The inclusion of the redriver provides a reduced bit error rate for the active channel, e.g., maintained below 10-10 for cables up to 3 meters as an example. The plotted line 702 indicating BER for the passive channel increases as a function of cable length, e.g., becoming prohibitively large (greater than 10-4) for cable lengths greater than 2 meters.

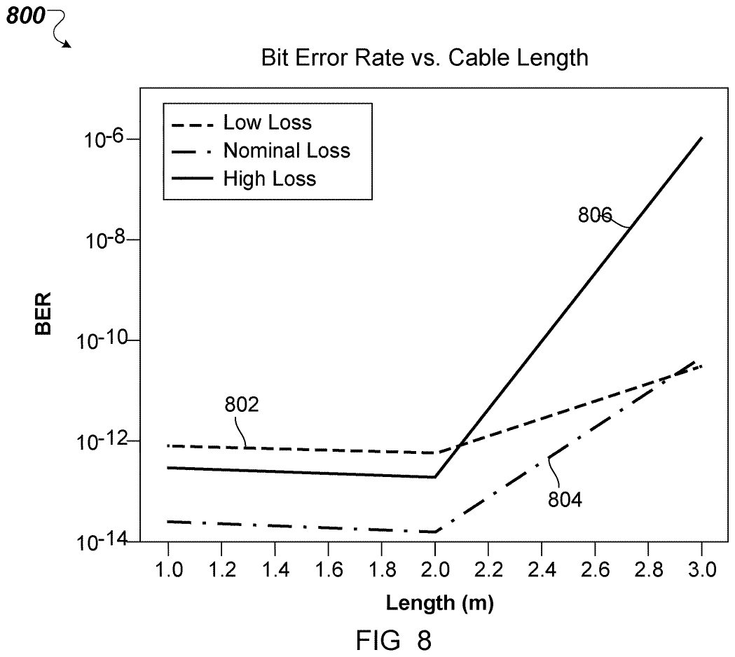

FIG. 8 is another example plot 800 of bit error rate vs. cable length. The plot 800 can be an example bit error rate using the redriver circuit 402 described above in reference to FIG. 4, e.g., relatively low BER below 10-4 for combinations of various typical host trace losses and cable lengths. The plot 800 includes plotted lines 802, 804, and 806 for different host traces. For example, the plotted line 802 is an example of low loss host trace that has 6.5 dB of combined package and host trace loss, with a BER below 10-12 up to 2 meters and below 10-10 at 3 meters. The one meter BER floor for the plotted line 802 can be dominated by linearity of the redriver circuit. The plotted line 804 can be an example of a nominal loss host trace that has 11.5 dB of combined package and host trace loss, with a BER below 10-13 up to 2 meters (e.g., improved relative to plotted line 802 because of the combination of smaller signal swing and driver linearity) and is below 10-10 at 3 meters. The plotted line 806 can be an example of a high loss host trace that has 16.5 dB of combined package and host trace loss, with a BER below 10-12 up to 2 meters and is slightly below 10-6 at 3 meters. The redriver can have a fixed setting and parameters and operate across all ranges of losses, e.g., reducing the need to any tuning, and thus be used for any combination of host trace loss, package loss, and cable length.

According to the analysis depicted in FIGS. 5 through 8, the redriver can operate as a large signal amplifier at very low frequencies, and a low noise amplifier at higher frequencies. The redriver can also handle imbalanced data, such as a PAM-4 sequence with long strings of identical consecutive bits, e.g., sequences with corresponding signals with a large magnitude at low frequencies.

In addition to the embodiments described above, the following embodiments are also innovative:

Embodiment 1 is a redriver circuit including:
an input block configured to receive signals;
a low-frequency attenuator coupled to the input block, the low-frequency attenuator configured to attenuate low-frequency components of the signals;
a low noise front end amplifier coupled to the low-frequency attenuator, the low noise front end amplifier configured to provide low-noise amplification to the attenuated low-frequency signals and maintain a target input impedance; and
an amplifier stage coupled to the low noise front end amplifier, wherein the amplifier stage can be configured to amplify output signals from the low noise front end amplifier and provide the amplified output signals.

Embodiment 2. The redriver circuit of embodiment 1, wherein the low-frequency attenuator includes a network configured to allow high frequency signals from the signals to bypass the network.

Embodiment 3. The redriver circuit of any one of embodiments 1 to 2, wherein the amplifier stage includes one or more amplifiers in a cascaded configuration.

Embodiment 4 is an apparatus including:
an active copper channel for connecting a first paddle card to a second paddle card, the second paddle card being different from the first paddle card, and the active copper channel including:
   a redriver circuit on the second paddle card; and
   one or more copper cables connecting the first paddle card to the second paddle card,
wherein the active copper channel allows for communication of signals between the first paddle card and the second paddle card.

Embodiment 5. The apparatus of embodiment 4, wherein the redriver circuit includes:
an input block configured to receive signals;
a low-frequency attenuator coupled to the input block, the low-frequency attenuator configured to attenuate low-frequency components of the signals;
a low noise front end amplifier coupled to the low-frequency attenuator, the low noise front end amplifier configured to provide low-noise amplification to the attenuated low-frequency signals and maintain a target input impedance; and
an amplifier stage coupled to the low noise front end amplifier, wherein the amplifier stage can be configured to amplify output signals from the low noise front end amplifier and provide the amplified output signals.

Embodiment 6. The apparatus of any one of embodiments 4 to 5, including an additional redriver circuit on the first paddle card.

Embodiment 7. The apparatus of any one of embodiments 4 to 6, wherein the additional redriver circuit includes:
an additional input block configured to receive signals;
an additional low-frequency attenuator coupled to the additional input block, the additional low-frequency attenuator configured to attenuate low-frequency components of the signals;
an additional low noise front end amplifier coupled to the additional low-frequency attenuator, the additional low noise front end amplifier configured to provide low-noise amplification to the attenuated low-frequency signals and maintain a target input impedance; and
an additional amplifier stage coupled to the additional low noise front end amplifier, wherein the amplifier stage can be configured to amplify output signals from the additional low noise front end amplifier and provide the amplified output signals.

Embodiment 8. The apparatus of any one of embodiments 4 to 7, further including:
a first high-speed connector coupled to the first paddle card and connected to a first printed circuit board; and
a second high-speed connector coupled to the second paddle card and connected to a second printed circuit board different than the first printed circuit board.

Embodiment 9. The apparatus of any one of embodiments 4 to 8, wherein at least one of (i) a first application specific integrated circuit (ASIC) is mounted onto the first printed circuit board and (ii) a second ASIC is mounted onto the second printed circuit board.

Embodiment 10. The apparatus of any one of embodiments 4 to 9, wherein:
the first ASIC includes (i) a first serializer/deserializer (SERDES) transmit circuit coupled to a first portion of the active copper channel and (ii) a first SERDES receive circuit coupled to the first portion of the active copper channel, and
the second ASIC includes (i) a second SERDES transmit circuit coupled to a second portion of the active copper channel different than the first portion of the active copper channel, and (ii) a second SERDES receive circuit coupled to the second portion of the active copper channel.

Embodiment 11. The apparatus of any one of embodiments 4 to 10, wherein the first SERDES transmit circuit includes one or more of (i) a first bit sequence generator, (ii) a first SERDES equalizer, (iii) a first SERDES output driver, (iv) a second SERDES output driver, and (v) a first set of package traces.

Embodiment 12. The apparatus of any one of embodiments 4 to 11, wherein the first SERDES transmit circuit includes the first set of package traces and the first set of package traces include traces between a first SERDES die of the first ASIC and the first printed circuit board.

Embodiment 13. The apparatus of any one of embodiments 4 to 12, wherein the first set of package traces include traces between the first SERDES die and a ball grid array of the first printed circuit board.

Embodiment 14. The apparatus of any one of embodiments 4 to 13, wherein the first SERDES receive circuit includes a second set of package traces between the first printed circuit board and a second SERDES die of the first ASIC.

Embodiment 15. The apparatus of any one of embodiments 4 to 14, wherein the first SERDES receive circuit includes receive equalizers configured to apply one or more of (i) continuous time linear equalization (CTLE), (ii) feed-forward equalization (FFE), (iii) decision feedback equalization (DFE), or Maximum Likelihood Sequence Estimation (MLSE) equalization.

Embodiment 16. The apparatus of any one of embodiments 4 to 15, wherein the second SERDES transmit circuit includes one or more of (i) a second bit sequence generator, (ii) a second SERDES equalizer, (iii) a third SERDES output driver, (iv) a fourth SERDES output driver, and (v) a second set of package traces.

Embodiment 17. The apparatus of any one of embodiments 4 to 16, wherein the second SERDES transmit circuit includes the second set of package traces and the second set of package traces include traces between a third SERDES die of the second ASIC and the second printed circuit board.

Embodiment 18. The apparatus of any one of embodiments 4 to 17, wherein the second set of package traces includes traces between the third SERDES die and a ball grid array of the second printed circuit board.

Embodiment 19. The apparatus of any one of embodiments 4 to 18, wherein the second SERDES receive circuit includes a fourth set of package traces between the second printed circuit board and a fourth SERDES die of the second ASIC.

Embodiment 20. The apparatus of any one of embodiments 4 to 19, wherein the second SERDES receive circuit includes second receive equalizers configured to apply one or more of (i) continuous time linear equalization (CTLE), (ii) feed-forward equalization (FFE), (iii) decision feedback equalization (DFE), or Maximum Likelihood Sequence Estimation (MLSE) equalization.

Embodiment 21 is an apparatus including:
an active copper channel for connecting a first paddle card to a second paddle card, the second paddle card being different from the first paddle card, and the active copper channel including:
   a redriver circuit on the first paddle card; and
   one or more copper cables connecting the first paddle card to the second paddle card,
wherein the active copper channel allows for communication of signals between the first paddle card and the second paddle card.

Embodiment 22. The apparatus of embodiment 21, wherein the redriver circuit includes:
an input block configured to receive signals;
a low-frequency attenuator coupled to the input block, the low-frequency attenuator configured to attenuate low-frequency components of the signals;
a low noise front end amplifier coupled to the low-frequency attenuator, the low noise front end amplifier configured to provide low-noise amplification to the attenuated low-frequency signals and maintain a target input impedance; and
an amplifier stage coupled to the low noise front end amplifier, wherein the amplifier stage can be configured to amplify output signals from the low noise front end amplifier and provide the amplified output signals.

Embodiment 23. The apparatus of any one of embodiments 21 to 22, including an additional redriver circuit on the first paddle card.

Embodiment 24. The apparatus of any one of embodiments 21 to 23, wherein the additional redriver circuit includes:
an additional input block configured to receive signals;
an additional low-frequency attenuator coupled to the additional input block, the additional low-frequency attenuator configured to attenuate low-frequency components of the signals;
an additional low noise front end amplifier coupled to the additional low-frequency attenuator, the additional low noise front end amplifier configured to provide low-noise amplification to the attenuated low-frequency signals and maintain a target input impedance; and
an additional amplifier stage coupled to the additional low noise front end amplifier, wherein the amplifier stage can be configured to amplify output signals from the additional low noise front end amplifier and provide the amplified output signals.

Embodiment 25. The apparatus of any one of embodiments 21 to 24, further including:
a first high-speed connector coupled to the first paddle card and connected to a first printed circuit board; and
a second high-speed connector coupled to the second paddle card and connected to a second printed circuit board different than the first printed circuit board.

Embodiment 26. The apparatus of any one of embodiments 21 to 25, wherein at least one of (i) a first application specific integrated circuit (ASIC) is mounted onto the first printed circuit board and (ii) a second ASIC is mounted onto the second printed circuit board.

Embodiment 27. The apparatus of any one of embodiments 21 to 26, wherein the first ASIC includes (i) a first serializer/deserializer (SERDES) transmit circuit coupled to a first portion of the active copper channel and (ii) a first SERDES receive circuit coupled to the first portion of the active copper channel, and
the second ASIC includes (i) a second SERDES transmit circuit coupled to a second portion of the active copper channel different than the first portion of the active copper channel, and (ii) a second SERDES receive circuit coupled to the second portion of the active copper channel.

Embodiment 28. The apparatus of any one of embodiments 21 to 27, wherein the first SERDES receive circuit includes a second set of package traces between the first printed circuit board and a second SERDES die of the first ASIC.

Some implementations can be implemented as circuit-based processes, including possible implementation on a single integrated circuit.

Unless explicitly stated otherwise, each numerical value and range should be interpreted as being approximate as if the word “about” or “approximately” preceded the value or range.

It will be further understood that various changes in the details, materials, and arrangements of the parts which have been described and illustrated to explain the nature of this disclosure can be made by those skilled in the art without departing from the scope of the disclosure, e.g., as expressed in the following claims.

The use of figure numbers and/or figure reference labels in the claims is intended to identify one or more possible implementations of the claimed subject matter in order to facilitate the interpretation of the claims. Such use is not to be construed as necessarily limiting the scope of those claims to the implementations shown in the corresponding figures.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one implementation” or “an implementation” means that a particular feature, structure, or characteristic described in connection with the implementation can be included in at least one implementation of the disclosure. The appearances of the phrase “in one implementation” in various places in the specification are not necessarily all referring to the same implementation, nor are separate or alternative implementations necessarily mutually exclusive of other implementations. The same applies to the term “implementation.”

Unless otherwise specified herein, the use of the ordinal adjectives “first,” “second,” “third,” etc., to refer to an object of a plurality of like objects merely indicates that different instances of such like objects are being referred to, and is not intended to imply that the like objects so referred-to have to be in a corresponding order or sequence, either temporally, spatially, in ranking, or in any other manner.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

As used herein in reference to an element and a standard, the term compatible means that the element communicates with other elements in a manner wholly or partially specified by the standard and would be recognized by other elements as sufficiently capable of communicating with the other elements in the manner specified by the standard. The compatible element does not need to operate internally in a manner specified by the standard.

The described implementations are to be considered in all respects as only illustrative and not restrictive. In particular, the scope of the disclosure is indicated by the appended claims rather than by the description and figures herein. All changes that come within the meaning and range of equivalency of the claims are to be embraced within their scope.

The description and drawings merely illustrate the principles of the disclosure. It will thus be appreciated that those of ordinary skill in the art will be able to devise various arrangements that, although not explicitly described or shown herein, embody the principles of the disclosure and are included within its spirit and scope. Furthermore, all examples recited herein are principally intended expressly to be only for pedagogical purposes to aid the reader in understanding the principles of the disclosure and the concepts contributed by the inventor(s) to furthering technology and are to be construed as being without limitation to such specifically recited examples and conditions.

The functions of the various elements shown in the figures, including any functional blocks labeled or referred to as “processors” and/or “controllers,” can be provided through the use of dedicated hardware as well as hardware capable of executing software in association with appropriate software. When provided by a processor, the functions can be provided by a single dedicated processor, by a single shared processor, or by a plurality of individual processors, some of which can be shared. Moreover, explicit use of the term “processor” or “controller” should not be construed to refer exclusively to hardware capable of executing software, and can implicitly include, without limitation, digital signal processor (DSP) hardware, network processor, application specific integrated circuit (ASIC), field programmable gate array (FPGA), read only memory (ROM) for storing software, random access memory (RAM), and non-volatile storage. Other hardware, conventional and/or custom, can also be included. Similarly, any switches shown in the figures are conceptual only. Their function can be carried out through the operation of program logic, through dedicated logic, through the interaction of program control and dedicated logic, or even manually, the particular technique being selectable by the implementer as more specifically understood from the context.

As used in this application, the term “circuitry” can refer to one or more or all of the following: (a) hardware-only circuit implementations (such as implementations in only analog and/or digital circuitry); (b) combinations of hardware circuits and software, such as (as applicable): (i) a combination of analog and/or digital hardware circuit(s) with software/firmware and (ii) any portions of hardware processor(s) with software (including digital signal processor(s)), software, and memory(ies) that work together to cause an apparatus, such as a mobile phone or switch, to perform various functions); and (c) hardware circuit(s) and or processor(s), such as a microprocessor(s) or a portion of a microprocessor(s), that requires software (e.g., firmware) for operation, but the software does not need to be present when it is not needed for operation. This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in switch, a cellular network device, or other computing or network device.

It should be appreciated by those of ordinary skill in the art that any block diagrams herein represent conceptual views of illustrative circuitry embodying the principles of the disclosure.

What is claimed is:

1. A redriver circuit comprising:
an input block configured to receive signals;
a low-frequency attenuator coupled to the input block, the low-frequency attenuator configured to attenuate low-frequency components of the signals;
a low noise front end amplifier coupled to the low-frequency attenuator, the low noise front end amplifier configured to provide low-noise amplification to the attenuated low-frequency signals and maintain a target input impedance; and
an amplifier stage coupled to the low noise front end amplifier, wherein the amplifier stage is configured to amplify output signals from the low noise front end amplifier and provide the amplified output signals.

2. The redriver circuit of claim 1, wherein the low-frequency attenuator comprises a network configured to allow high frequency signals from the signals to bypass the network.

3. The redriver circuit of claim 1, wherein the amplifier stage comprises one or more amplifiers in a cascaded configuration.

4. An apparatus comprising:
an active copper channel for connecting a first paddle card to a second paddle card, the second paddle card being different from the first paddle card, and the active copper channel comprising:
a redriver circuit on the second paddle card; and
one or more copper cables connecting the first paddle card to the second paddle card,
wherein the active copper channel allows for communication of signals between the first paddle card and the second paddle card.

5. The apparatus of claim 4, wherein the redriver circuit comprises:
an input block configured to receive signals;
a low-frequency attenuator coupled to the input block, the low-frequency attenuator configured to attenuate low-frequency components of the signals;
a low noise front end amplifier coupled to the low-frequency attenuator, the low noise front end amplifier configured to provide low-noise amplification to the attenuated low-frequency signals and maintain a target input impedance; and
an amplifier stage coupled to the low noise front end amplifier, wherein the amplifier stage is configured to amplify output signals from the low noise front end amplifier and provide the amplified output signals.

6. The apparatus of claim 4, comprising an additional redriver circuit on the first paddle card.

7. The apparatus of claim 6, wherein the additional redriver circuit comprises:
an additional input block configured to receive signals;
an additional low-frequency attenuator coupled to the additional input block, the additional low-frequency attenuator configured to attenuate low-frequency components of the signals;
an additional low noise front end amplifier coupled to the additional low-frequency attenuator, the additional low noise front end amplifier configured to provide low-noise amplification to the attenuated low-frequency signals and maintain a target input impedance; and
an additional amplifier stage coupled to the additional low noise front end amplifier, wherein the amplifier stage is configured to amplify output signals from the additional low noise front end amplifier and provide the amplified output signals.

8. The apparatus of claim 4, further comprising:
a first high-speed connector coupled to the first paddle card and connected to a first printed circuit board; and
a second high-speed connector coupled to the second paddle card and connected to a second printed circuit board different than the first printed circuit board.

9. The apparatus of claim 8, wherein at least one of (i) a first application specific integrated circuit (ASIC) is mounted onto the first printed circuit board and (ii) a second ASIC is mounted onto the second printed circuit board.

10. The apparatus of claim 9, wherein:
the first ASIC comprises (i) a first serializer/deserializer (SERDES) transmit circuit coupled to a first portion of the active copper channel and (ii) a first SERDES receive circuit coupled to the first portion of the active copper channel, and
the second ASIC comprises (i) a second SERDES transmit circuit coupled to a second portion of the active copper channel different than the first portion of the active copper channel, and (ii) a second SERDES receive circuit coupled to the second portion of the active copper channel.

11. The apparatus of claim 10, wherein the first SERDES transmit circuit comprises one or more of (i) a first bit sequence generator, (ii) a first SERDES equalizer, (iii) a first SERDES output driver, (iv) a second SERDES output driver, and (v) a first set of package traces.

12. The apparatus of claim 11, wherein the first SERDES transmit circuit comprises the first set of package traces and the first set of package traces comprise traces between a first SERDES die of the first ASIC and the first printed circuit board.

13. The apparatus of claim 12, wherein the first set of package traces comprise traces between the first SERDES die and a ball grid array of the first printed circuit board.

14. The apparatus of claim 10, wherein the first SERDES receive circuit comprises a second set of package traces between the first printed circuit board and a second SERDES die of the first ASIC.

15. The apparatus of claim 14, wherein the first SERDES receive circuit comprises receive equalizers configured to apply one or more of (i) continuous time linear equalization (CTLE), (ii) feed-forward equalization (FFE), (iii) decision feedback equalization (DFE), or Maximum Likelihood Sequence Estimation (MLSE) equalization.

16. The apparatus of claim 10, wherein the second SERDES transmit circuit comprises one or more of (i) a second bit sequence generator, (ii) a second SERDES equalizer, (iii) a third SERDES output driver, (iv) a fourth SERDES output driver, and (v) a second set of package traces.

17. The apparatus of claim 16, wherein the second SERDES transmit circuit comprises the second set of package traces and the second set of package traces comprise traces between a third SERDES die of the second ASIC and the second printed circuit board.

18. The apparatus of claim 17, wherein the second set of package traces comprises traces between the third SERDES die and a ball grid array of the second printed circuit board.

19. The apparatus of claim 10, wherein the second SERDES receive circuit comprises a fourth set of package traces between the second printed circuit board and a fourth SERDES die of the second ASIC.

20. The apparatus of claim 19, wherein the second SERDES receive circuit comprises second receive equalizers configured to apply one or more of (i) continuous time linear equalization (CTLE), (ii) feed-forward equalization (FFE), (iii) decision feedback equalization (DFE), or Maximum Likelihood Sequence Estimation (MLSE) equalization.
